(19) United States
(12) Patent Application Publication
(10) Pub. No.: US 2011/0001734 A1
(43) Pub. Date: Jan. 6, 2011

(54) PLASMA DISPLAY APPARATUS

(75) Inventor: Seong Soo KIM, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/795,953

(22) Filed: Jun. 8, 2010

(30) Foreign Application Priority Data
Jul. 6, 2009 (KR) 2009-61027

(51) Int. Cl. G09G 5/00; H05K 7/00

(52) U.S. Cl. 345/204; 361/679.01

(57) ABSTRACT

A plasma display apparatus with a slim shape including a speaker and ElectroMagnetic Interference (EMI) line filter being arranged at a rear surface of a chassis member of a Plasma Display Panel (PDP) module.

### CROSS-REFERENCE TO RELATED APPLICATIONS

This application claims priority under 35 U.S.C. §119(a) from Korean Patent Application No. 2009-0061027, filed on Jul. 6, 2009 in the Korean Intellectual Property Office, the disclosure of which is incorporated herein in its entirety by reference.

### BACKGROUND

1. Field of the Invention

Embodiments of the present general inventive concept relate to a plasma display device having a slim shape and compact configuration.

2. Description of the Related Art

Generally, a Plasma Display Panel (hereinafter, referred to as a PDP) is a flat panel display using gas discharge. A display apparatus using a PDP (hereinafter, referred to as a plasma display apparatus) may be easily made thinner, lighter and with a great viewing angle than a Cathode Ray Tube (CRT) display apparatus and thus is highlighted as a next generation display apparatus.

Such a plasma display apparatus, however, exhibits considerable power consumption and high generation of electromagnetic waves harmful to the human body and therefore, may need means to prevent leakage of electromagnetic waves.

A plasma display apparatus includes a PDP consisting of a front panel and rear panel to realize images, a chassis member coupled to a rear surface of the PDP, on which a plurality of circuit boards to operate the PDP is arranged, and a body in which the PDP and chassis member are received. The chassis member functions not only to support the PDP made of glass, but also as a heat sink for the PDP.

In the above-described plasma display apparatus, the body may need at least a space to install, e.g., a stand to keep the body upright on the ground surface, a speaker that outputs sound, and a filter to reduce electromagnetic waves of a power line connected to an external power source. Therefore, reduction in the thickness of the body of the plasma display apparatus may be limited.

### SUMMARY

Therefore, exemplary embodiments of the present general inventive concept provide a plasma display apparatus that may be slim and compact.

Additional features and utilities of the present general inventive concept will be set forth in part in the description which follows and, in part, will be obvious from the description, or may be learned by practice of the general inventive concept.

Example embodiments of the present general inventive concept may provide a plasma display apparatus includes a front frame having a window, a Plasma Display Panel (PDP) module seated on an edge of the front frame to contact the edge and including a panel assembly and a chassis member coupled to a rear surface of the panel assembly, and a rear cover coupled to the front frame to define a space in which the PDP module is received, where the rear surface of the chassis member includes a drive circuit board to drive the panel assembly, an image board to receive image signals and to generate control signals to drive the panel assembly, a logic board to control the drive circuit board, a power board to supply power required to drive the board, a speaker to output sound, and an ElectroMagnetic Interference (EMI) line filter to reduce EMI from a power line.

The plasma display apparatus may further include a supporting frame to couple the PDP module to the front frame by pressing an edge of the PDP module.

The supporting frame may have a stepped portion, and one end of the supporting frame includes a press portion to press an edge of the chassis member and the other end being includes a fixing portion fixed to the front frame with a fastener.

The PDP module may further include a filter layer arranged on a front surface of the PDP module to intercept electromagnetic waves generated by operation of the panel assembly, and a reflective layer that is provided on a front surface of the filter layer.

The plasma display apparatus may further include a stand member to position the PDP module in a first direction on a surface.

The stand member may include a base, a vertical post extending from the base, and a coupling plate provided at an end of the vertical post and coupled to the PDP module.

A fixing bracket may be provided at the rear surface of the chassis member.

The fixing bracket may include a first coupling portion formed at one side of the fixing bracket and that is coupled to the chassis member, a second coupling portion coupled to the edge of the front frame, and an inwardly bent supporting portion to support the PDP module.

The rear cover may have an opening shaped to correspond to the coupling plate to allow the coupling plate to protrude from the rear cover.

Example embodiments of the present general inventive concept may also provide a plasma display apparatus includes a body including a front frame formed with a window and a rear cover coupled with the front frame thus defining an interior space, a Plasma Display Panel (PDP) module including a panel assembly having a front substrate and a rear substrate, and a chassis member coupled to a rear surface of the rear substrate, the chassis member being integrally mounted with a circuit board assembly to drive the panel assembly, a speaker to output sound, and an ElectroMagnetic Interference (EMI) filter to reduce EMI flowing in a power line, a supporting frame to support the PDP module to come into close contact with the front frame, and a stand member mounted to a fixing bracket coupled to the chassis member to position the body in a first direction on a surface.

Exemplary embodiments of the present general inventive concept also provide a control apparatus to control a display apparatus, including at least one drive circuit board to control the display apparatus, at least one speaker, a power supply to power at least the at least one drive circuit board, a line filter to minimize the electromagnetic interference generated from at least a power line from the power supply, where the at least one speaker, the at least one drive circuit board, the power supply, and the line filter are mounted in a first direction on a chassis member so as to minimize a thickness of the control apparatus.

Exemplary embodiments of the present general inventive concept also provide a display apparatus, including a display panel, at least one drive circuit board to control the display apparatus, at least one speaker, a power supply to power at least the at least one drive circuit board, a line filter to minimize the electromagnetic interference generated from at least a power line from the power supply, wherein the at least one speaker, the at least one drive circuit board, the power supply, and the line filter are mounted in a first direction on a chassis member so as to minimize the thickness of the display apparatus.

Exemplary embodiments of the present general inventive concept also provide a plasma display apparatus, including a chassis member having a first side and a second side, a plasma display panel mounted to the first side of the chassis member, at least one drive circuit board mounted to the second side of the chassis member to control at least the plasma display panel, at least one speaker mounted on the second side of the chassis member, a power supply mounted to the second side of the chassis member to power at least the at least one drive circuit board, and a line filter mounted to the second side of the chassis to minimize the electromagnetic interference generated from at least a power line from the power supply, where the at least one speaker, the at least one drive circuit board, the power supply, and the line filter are mounted lengthwise on the chassis member so as to minimize a width of the plasma display apparatus.

Exemplary embodiments of the present general inventive concept also provide a control apparatus to control a display apparatus, including a chassis member having a first side to receive a display panel of the display apparatus and a second side, at least one drive circuit board mounted to the second side of the chassis member to control the display apparatus, at least one speaker mounted adjacent to the at least one drive circuit board, a power supply mounted to the second side of the chassis member to power at least the at least one drive circuit board, a line filter mounted to the second side of the chassis to minimize the electromagnetic interference generated from at least a power line from the power supply, where the at least one speaker, the at least one drive circuit board, the power supply, and the line filter are mounted lengthwise on the chassis member so as to minimize the width of the control apparatus.

### BRIEF DESCRIPTION OF THE DRAWINGS

These and/or other features and utilities of the present general inventive concept will become apparent and more readily appreciated from the following description of the embodiments, taken in conjunction with the accompanying drawings of which:

FIG. 1 illustrates an exploded perspective view of a plasma display apparatus according to exemplary embodiments of the present general inventive concept;

FIG. 2 is a sectional view schematically illustrating a PDP module included in the plasma display apparatus according to exemplary embodiments of the present general inventive concept;

FIG. 3 is a view illustrating the arrangement of a circuit board assembly mounted on a rear surface of a chassis member included in the plasma display apparatus according to exemplary embodiments of the present general inventive concept;

FIG. 4 is a perspective view illustrating the coupling of a front frame and PDP module included in the plasma display apparatus according to exemplary embodiments of the present general inventive concept;

FIG. 5 is a partially cut-away view illustrating a coupled state of the front frame and PDP module according to exemplary embodiments of the present general inventive concept;

FIG. 6 is a perspective view illustrating the coupling of a stand member and rear cover included in the plasma display apparatus according to exemplary embodiments of the present general inventive concept; and

FIG. 7 is a perspective view illustrating the rear surface of the plasma display apparatus according to exemplary embodiments of the present general inventive concept.

### DETAILED DESCRIPTION OF THE EMBODIMENTS

Reference will now be made in detail to the exemplary embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a plasma display apparatus according to exemplary embodiments of the present general inventive concept will be described.

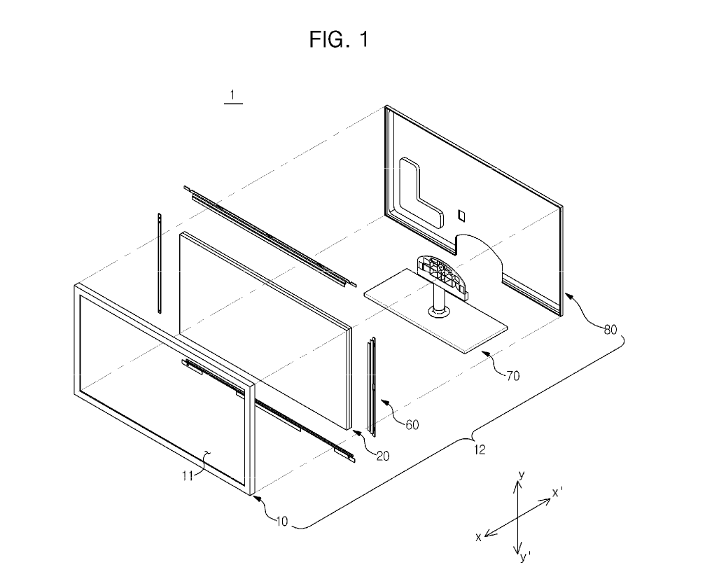

FIG. 1 illustrates an exploded perspective view of a plasma display apparatus according to exemplary embodiments of the present general inventive concept.

Referring to FIG. 1, the plasma display apparatus 1 according to the exemplary embodiments of the present general inventive concept can include a front frame 10 having a window 11, a PDP module 20 to form one or more images, supporting frames 60 to couple the PDP module 20 to the front frame 10 such that the PDP module 20 contacts the front frame 10, and a rear cover 80 that defines an interior space together with the front frame 10.

The front frame 10 and rear cover 80 can be coupled with each other to be at least part of a body 12 to define an external appearance of the plasma display apparatus 1. The body 12 may be kept upright on a surface (e.g., a tabletop or any other suitable flat surface) via a stand member 70.

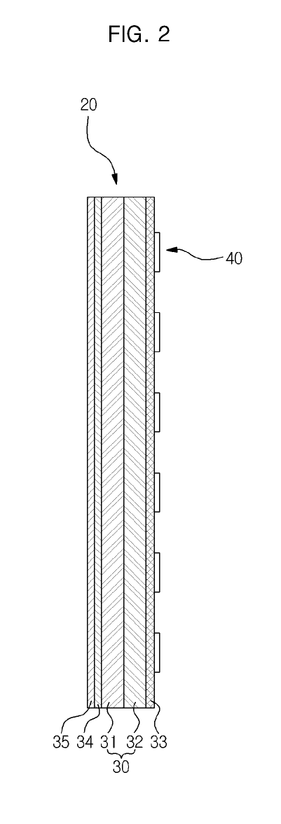

FIG. 2 is a sectional view schematically illustrating the PDP module 20 included in the plasma display apparatus 1 according to exemplary embodiments of the present general inventive concept.

Referring to FIG. 2, the PDP module 20 can include a panel assembly 30 and a chassis member 33 that can be coupled to a rear surface of the panel assembly 30.

The panel assembly 30 can include a front substrate 31, and a rear substrate 32 arranged at the rear of the front substrate 31. Both the front substrate 31 and rear substrate 32 can be made of transparent material, such as glass or transparent synthetic resin.

Discharge cells can be arranged between the front substrate 31 and the rear substrate 32 and can be separated from one another by partitions (not illustrated). The discharge cells can be charged with discharge gas. In addition, phosphors can be applied to predetermined regions of the partitions.

A plurality of address electrodes (not illustrated) can be arranged parallel to one another or in any other suitable arrangement to carry out the exemplary embodiments of the present general inventive concept as described herein on the rear substrate 32. Discharge sustain electrode pairs (not illustrated) can be arranged on the front substrate 31, to intersect the address electrodes. If a voltage is applied to the electrodes, a discharge can occur from the gas between the electrodes. Radiation of ultraviolet rays when the discharge occurs can excite the phosphors such that the phosphors to emit light for image formation.

The front substrate 31 can be provided on a front surface thereof with a filter layer 34 to intercept electromagnetic waves generated by operation of the panel assembly 30.

The filter layer 34 may be formed by depositing a thin highly conductive transparent film, or by depositing a metal conductive film that is processed by photolithographic etching of conductive material (e.g., gold, silver, copper).

A reflective layer 35 can be provided on a front surface of the filter layer 34 to intercept near infrared rays and components of light discharged from the panel assembly 30 that may interfere with the display of an image by the plasma display apparatus 1.

The reflective layer 35 can be formed by laminating and/or coating the reflective layer 35 with an Anti-Reflection (AR) film, or by coating the layer 35 with a reflective paint or layer of reflective material.

Thereby, the reflective layer 35 may minimize and/or prevent reflection of the light discharged from the panel assembly 30. More particularly, the reflective layer 35 may minimize the interference of a light component with an image formed by the plasma display apparatus 1 with image signals. The reflective layer 35 may minimize and/or reduce diffuse reflectance of outside light (e.g., incident light on the reflective layer 35) to increase and/or enhance image boundary conditions.

A circuit board assembly 40 can be installed and/or affixed to the chassis member 33 provided at the rear surface (e.g., adjacent to the rear substrate 32) of the panel assembly 30 and can transmit electric signals to the respective electrodes of the panel assembly 30.

The chassis member 33 may be formed from and/or include at least one metal material having an increased thermal conduction rate to emit heat generated from the panel assembly 30. That is, the chassis member 33 may draw heat generated by the panel assembly 30, and may dissipate the heat. The chassis member 33 may be adhered by, e.g., a double-sided adhesive (not illustrated) or any other suitable affixing material or fastener when a heat conductive sheet (not illustrated) is interposed between the chassis member 33 and the rear surface of the panel assembly 30.

The PDP module 20 may be a single module in which the panel assembly 30, filter layer 34, reflective layer 35, and chassis member 33 are coupled with one another.

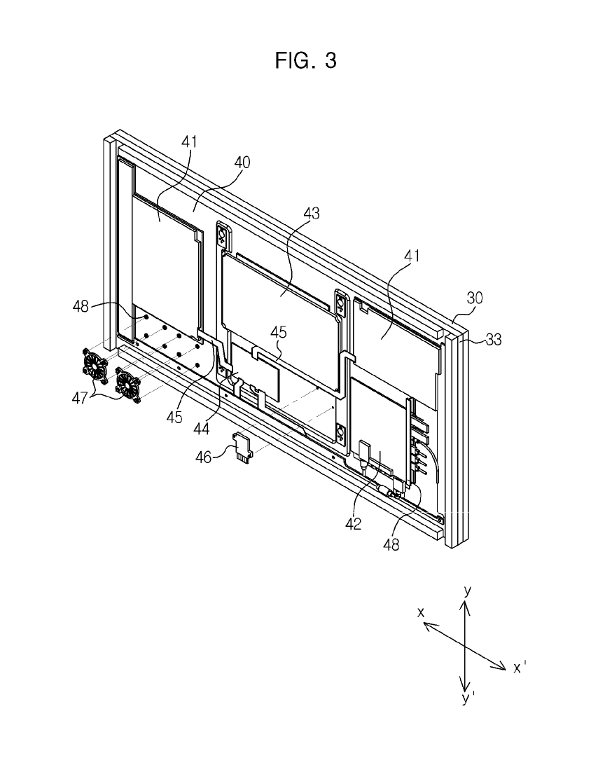

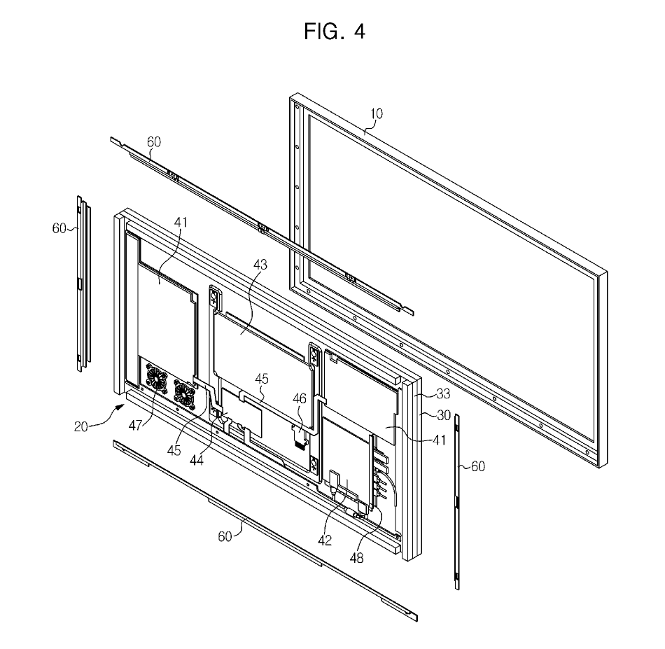

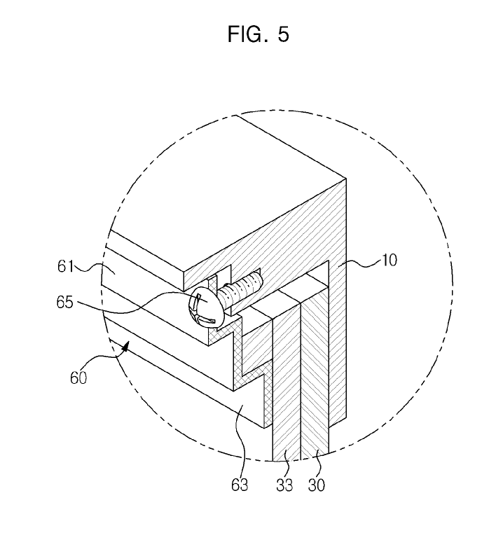

FIG. 3 is a view illustrating the arrangement of the circuit board assembly mounted on a rear surface of the chassis member included in the plasma display apparatus according to exemplary embodiments of the present general inventive concept. FIG. 4 is a perspective view illustrating the coupling of the front frame and PDP module included in the plasma display apparatus according to exemplary embodiments of the present general inventive concept. FIG. 5 is a partially cut-away view illustrating a coupled state of the front frame and PDP module according to exemplary embodiments of the present general inventive concept. The utilities and features illustrated in FIGS. 3-5 will be disclosed in detail below.

Referring to FIG. 3, the circuit board assembly 40, on which circuit devices to drive the panel assembly 30 are mounted, can be coupled to a rear surface of the chassis member 33.

The circuit board assembly 40 can include drive circuit boards 41 mounted on one side or both sides of the rear surface of the chassis member 33, an image board 42 mounted below one of the drive circuit boards 41 (e.g., below the drive circuit board 41 on the right side (in the X′ direction) of the circuit board assembly 40 as illustrated in FIG. 3), and a Switching Mode Power Supply (SMPS) 43 and logic board 44 mounted respectively at upper (in the Y-direction) and lower positions (in the Y′-direction) in the center of the rear surface of the chassis member 33 as illustrated in FIG. 3. The mounted positions of at least the drive circuit board 41, the image board 42, the switching mode power supply 43, and the logic board 44 illustrated in FIG. 3 may be example mounting positions, and boards 41, 42, 44 and SMPS 43 may be mounted in other suitable positions to carry out the exemplary embodiments of the present general inventive concept as described herein.

The drive circuit board 41 can be electrically connected to the panel assembly 30 via a signal transmission medium, such as, e.g., a Tape Carrier Package (TCP) or Flexible Printed Circuit (FPC), to apply a predetermined signal voltage to the electrodes disposed in the panel assembly 30.

The image board 42 can receive image signals from the outside (e.g., from a processor, a computer, a server, a digital camera, a personal digital assistant, smartphone, or any other suitable device to carry out the exemplary embodiments of the present general inventive concept as disclosed herein) via input terminals and can drive the electrodes in the panel assembly 30 with one or more control signals.

The image board 42 may be supported by a bracket 48 and may be fixed to the rear surface of the chassis member 33 via fastening members, such as screws, etc.

The logic board 44 can control the drive circuit boards 41 with one or more control signals, according to the image signals transmitted from the image board 42.

The SMPS 43 can supply power to the PDP module 20 to drive the PDP module 20.

The above-described components of the circuit board assembly 40 can be electrically connected to one another using cables 45, which include power lines to transmit power between the respective circuit boards (e.g., between the drive circuit boards 41, the image board 41, the logic board 44 and the SMPS 43, etc.) and signal lines to transmit drive data (e.g., data from the image board 42 to the drive circuit boards 41, data from the drive circuit boards 41 to the PDP module 20, etc.). That is, cables 45 can include power lines to supply power and signal lines to transmit data.

Speakers 47 can be arranged below one of the drive circuit boards 41 and can output sound according to audio signals received by the speakers 47. For example, as illustrated in FIG. 3, the speakers 47 can be arranged below (in the Y′-direction) the drive circuit board 41 on the left side (e.g., in the X-direction) of the circuit board assembly 40. The speakers 47 can be mounted to the bracket 48 of the chassis member 33 via screws and/or other suitable fasteners. Although the speakers 47 are illustrated in FIG. 3 as being disposed below a left one of the drive circuit boards 41, the speakers 47 may be mounted to the chassis member 33 in any suitable location to carry out the exemplary embodiments of the present general inventive concept as described herein.

An ElectroMagnetic Interference (EMI) line filter 46 can be disposed on the chassis member 33 at, for example, a position below (e.g., in the Y′-Direction) the SMPS 43 and can reduce and/or minimize EMI flowing in a power line received by the EMI line filter 46, a power switch of which is connected to an internal circuit.

As the speakers 47 and EMI line filter 46 can be integrally coupled to the rear surface of the chassis member 33, the PDP module 20 can have a slim shape (e.g., at least the width of the PDP module 20 may be minimized).

The PDP module 20, as illustrated in FIG. 4, can contact an inner surface of the front frame 10 and a plurality of the sides (e.g., each of four sides) of the PDP module 20 can be supported by the supporting frame 60 so as to be fixed to the inner surface of the front frame 10.

A plurality of discrete supporting frames 60 (e.g., four supporting frames 60 as illustrated in FIG. 4) can be located at outer edges of the PDP module 20, respectively. The supporting frames 60 can be coupled to the front frame 10 via fastening members 65, such as screws, etc., such that the PDP module 20 contacts and/or comes into close contact with the front frame 10.

The supporting frame 60, as illustrated in FIG. 5, is formed by bending a metal panel to have a stepped portion. One end of the supporting frame 60 can be formed with a press portion 63 to press an edge of the chassis member 33 of the PDP module 20. The other end of the supporting frame 60 can be formed with a fixing portion 61 fixed to the front frame 10 via the fastening members 65.

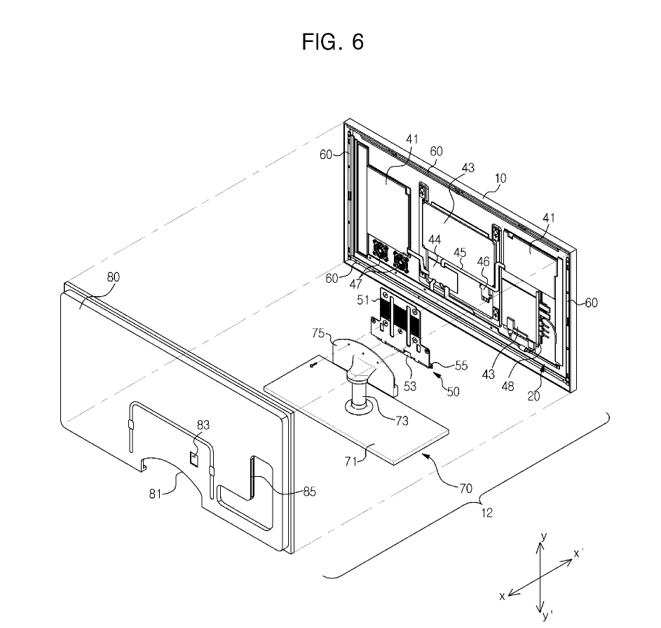

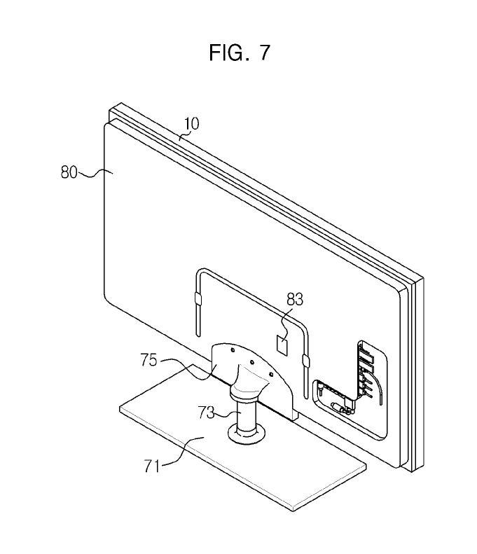

FIG. 6 is a perspective view illustrating the coupling relationship of the stand member and rear cover included in the plasma display apparatus according to exemplary embodiments of the present general inventive concept. FIG. 7 is a perspective view illustrating the rear surface of the plasma display apparatus according to exemplary embodiments of the present general inventive concept.

Referring to FIG. 6, the stand member 70 can position the PDP module 20 upright on a surface (e.g., a ground surface or any other suitable flat surface) includes a base 71 to support a load of the plasma display apparatus 1, a vertical post 73 extending upward (e.g., in the Y-direction) from the base 71 to position the plasma display apparatus 1 upright (e.g., extending in the Y-direction), and a coupling plate 75 provided at an end of the vertical post 73 to couple the stand member 70 to the plasma display apparatus 1.

A fixing bracket 50, to which the coupling plate 75 of the stand member 70 can be coupled, can be, for example, provided below (e.g., in the Y′-direction) the center of the rear surface of the chassis member 33 included in the PDP module 20, or in any other suitable position to carry out the exemplary embodiments of the present general inventive concept as described herein.

The fixing bracket 50 may have a first coupling portion 51 formed at one side thereof, the first coupling portion 51 being coupled to the rear surface of the chassis member 33. The fixing bracket 50 may have a second coupling portion 53 and inwardly bent supporting portion 55 formed at the other side thereof. The second coupling portion 53 can be coupled to a lower (e.g., in the Y′ direction) edge of the front frame 10 via screws, etc. The inwardly bent supporting portion 55 can be formed at a position adjacent to the second coupling portion 53 and can support the bottom (e.g., toward the Y′ direction) of the PDP module 20 when the fixing bracket 50 is coupled to the PDP module 20.

Thereby, the fixing bracket 50 may minimize and/or prevent sag of the chassis member 33, and provide and/or increase the rigidity of the chassis member 33 when the chassis member 33 is coupled with the stand member 70.

The rear cover 80 can be coupled to the front frame 10 via fastening members, screws, etc., and can surround the front frame 10 at least in part from the rear side thereof when the PDP module 20 and supporting frames 60 are coupled to the front frame 10.

The rear cover 80 can have an opening 81 formed in a center lower position thereof, the opening 81 having a shape corresponding to the coupling plate 75 of the stand member 70. As illustrated in FIG. 7, when the rear cover 80 is coupled, the coupling plate 75 of the stand member 70 can protrude from the rear cover 80 through the opening 81.

The rear cover 80 can have a cable hole 83 formed at a position corresponding to the EMI line filter 46 to provide a connection between the EMI line filter 46 and a power cable, and a terminal slot 85 through which input/output terminals of the image board 42 can be exposed.

Accordingly, if the front frame 10, PDP module 20, supporting frame 60, rear cover 80, and stand member 70 are coupled to the plasma display apparatus 1, the plasma display apparatus 1 according to exemplary embodiments of the present general inventive concept may maintain a narrow body depth. That is, the width of plasma display apparatus 1 (e.g., in the X-direction) may be minimized. As the chassis member 33 of the PDP module 20 may be integrally provided with the speakers 47 and EMI line filter 46, the plasma display apparatus 1 may have a slim shape and compact configuration with a reduced product thickness such that the width of plasma display apparatus 1 (e.g., in the X to X′ direction) may be minimized.

As is apparent from the above description, by integrally mounting a speaker and EMI line filter to a chassis member of a PDP module, a plasma display apparatus according to exemplary embodiments of the present general inventive concept may achieve a slim shape with a reduced body thickness.

Although several example embodiments of the present general inventive concept have been illustrated and described, it would be appreciated by those skilled in the art that changes may be made in these embodiments without departing from the principles and spirit of the general inventive concept, the scope of which is defined in the claims and their equivalents.

What is claimed is:

1. A plasma display apparatus, comprising:
a front frame having a window;
a Plasma Display Panel (PDP) module seated on an edge of the front frame to contact the edge and including a panel assembly and a chassis member coupled to a rear surface of the panel assembly; and
a rear cover coupled to the front frame to define a space in which the PDP module is received,
wherein the rear surface of the chassis member includes a drive circuit board to drive the panel assembly, an image board to receive image signals and to generate control signals to drive the panel assembly, a logic board to control the drive circuit board, a power board to supply power required to drive the board, a speaker to output sound, and an ElectroMagnetic Interference (EMI) line filter to reduce EMI from a power line.

2. The apparatus according to claim 1, further comprising:
a supporting frame to couple the PDP module to the front frame by pressing an edge of the PDP module.

3. The apparatus according to claim 2, wherein the supporting frame has a stepped portion, and
wherein one end of the supporting frame includes a press portion to press an edge of the chassis member and the other end includes a fixing portion fixed to the front frame with a fastener.

4. The apparatus according to claim 1, wherein the PDP module further comprises:
a filter layer arranged on a front surface of the PDP module to intercept electromagnetic waves generated by operation of the panel assembly, and
wherein a reflective layer is provided on a front surface of the filter layer.

5. The apparatus according to claim 1, further comprising:
a stand member to position the PDP module in a first direction on a surface.

6. The apparatus according to claim 5, wherein the stand member comprises:
a base;
a vertical post extending from the base; and
a coupling plate provided at an end of the vertical post and coupled to the PDP module.

7. The apparatus according to claim 6, further comprising:
a fixing bracket provided at the rear surface of the chassis member,
wherein the coupling plate is coupled to the fixing bracket.

8. The apparatus according to claim 7, wherein the fixing bracket comprises:
a first coupling portion formed on one side of the fixing bracket and that is coupled to the chassis member;
a second coupling portion coupled to the edge of the front frame; and
an inwardly bent supporting portion to support the PDP module.

9. The apparatus according to claim 8, wherein the rear cover comprises:
an opening shaped to correspond to the coupling plate to allow the coupling plate to protrude from the rear cover.

10. A plasma display apparatus, comprising:
a body including a front frame formed with a window and a rear cover coupled with the front frame to define an interior space;
a Plasma Display Panel (PDP) module including a panel assembly having a front substrate and a rear substrate, and a chassis member coupled to a rear surface of the rear substrate, the chassis member being integrally mounted with a circuit board assembly to drive the panel assembly, a speaker to output sound, and an ElectroMagnetic Interference (EMI) filter to reduce EMI flowing in a power line;
a supporting frame to support the PDP module so to contact the front frame; and
a stand member mounted to a fixing bracket coupled to the chassis member to position the body in a first direction on a surface.

11. A control apparatus to control a display apparatus, comprising:
at least one drive circuit board to control the display apparatus;
at least one speaker;
a power supply to power at least the at least one drive circuit board;
a line filter to minimize the electromagnetic interference generated from at least a power line from the power supply,
wherein the at least one speaker, the at least one drive circuit board, the power supply, and the line filter are mounted in a first direction on a chassis member so as to minimize a thickness of the control apparatus.

12. A display apparatus, comprising:
a display panel;
at least one drive circuit board to control the display apparatus;
at least one speaker;
a power supply to power at least the at least one drive circuit board;
a line filter to minimize the electromagnetic interference generated from at least a power line from the power supply,
wherein the at least one speaker, the at least one drive circuit board, the power supply, and the line filter are mounted in a first direction on a chassis member so as to minimize the thickness of the display apparatus.

13. A plasma display apparatus, comprising:
a chassis member having a first side and a second side;
a plasma display panel mounted to the first side of the chassis member;
at least one drive circuit board mounted to the second side of the chassis member to control at least the plasma display panel;
at least one speaker mounted on the second side of the chassis member;
a power supply mounted to the second side of the chassis member to power at least the at least one drive circuit board; and
a line filter mounted to the second side of the chassis to minimize the electromagnetic interference generated from at least a power line from the power supply,
wherein the at least one speaker, the at least one drive circuit board, the power supply, and the line filter are mounted lengthwise on the chassis member so as to minimize a width of the plasma display apparatus.

14. A control apparatus to control a display apparatus, comprising:
a chassis member having a first side to receive a display panel of the display apparatus and a second side;
at least one drive circuit board mounted to the second side of the chassis member to control the display apparatus;
at least one speaker mounted adjacent to the at least one drive circuit board;
a power supply mounted to the second side of the chassis member to power at least the at least one drive circuit board;
a line filter mounted to the second side of the chassis to minimize the electromagnetic interference generated from at least a power line from the power supply,
wherein the at least one speaker, the at least one drive circuit board, the power supply, and the line filter are mounted lengthwise on the chassis member so as to minimize the width of the control apparatus.
